(19) United States
(12) Patent Application Publication
(10) Pub. No.: US 2016/0301351 A1
(43) Pub. Date: Oct. 13, 2016

(54) GATE DRIVING CIRCUIT, INVERTER CIRCUIT, AND MOTOR CONTROL DEVICE

(71) Applicant: KABUSHIKI KAISHA YASKAWA DENKI, Kitakyushu-shi (JP)

(72) Inventor: Heiji KANEDA, Kitakyushu-shi (JP)

(73) Assignee: KABUSHIKI KAISHA YASKAWA DENKI, Kitakyushu-shi (JP)

(21) Appl. No.: 15/188,994

(22) Filed: Jun. 22, 2016

Related U.S. Application Data
(63) Continuation of application No. PCT/JP2014/051272, filed on Jan. 22, 2014.

(51) Int. Cl. H02P 29/032; H02M 7/5387; H02P 27/08; H03K 17/16; H03K 17/0812; H02M 1/088; H02P 6/14

(52) U.S. Cl. CPC H02P 29/032; H02M 1/088; H02M 7/5387; H02P 6/14; H03K 17/162; H03K 17/08122; H02P 27/08

(57) ABSTRACT

This disclosure discloses a gate driving circuit configured to control conduction or shutdown of a semiconductor switching element. The gate driving circuit includes a gate control part, a gate resistor, and a short circuit part. The gate control part is configured to output a gate control signal for controlling the conduction or the shutdown of the semiconductor switching element. The gate resistor is coupled between the gate control part and a gate electrode of the semiconductor switching element. The short circuit part is coupled in parallel with the gate resistor and configured to shirt-circuit the gate resistor.

### CROSS-REFERENCE TO RELATED APPLICATION

This is a continuation application of PCT/JP2014/051272, filed Jan. 22, 2014, which was published under PCT article 21(2).

### TECHNICAL FIELD

Embodiments of the disclosure relate to a gate driving circuit, an inverter circuit, and a motor control device.

### BACKGROUND

A configuration in which a gate resistor RG is disposed in order to prevent generation of a surge voltage in a switching element is known.

### SUMMARY

According to one aspect of the disclosure, there is provided a gate driving circuit configured to control conduction or shutdown of a semiconductor switching element. The gate driving circuit includes a gate control part, a gate resistor, and a short circuit part. The gate control part is configured to output a gate control signal for controlling the conduction or the shutdown of the semiconductor switching element. The gate resistor is coupled between the gate control part and a gate electrode of the semiconductor switching element. The short circuit part is coupled in parallel with the gate resistor and configured to shirt-circuit the gate resistor.

### BRIEF DESCRIPTION OF THE DRAWING

FIG. 1 is a diagram schematically showing a circuit configuration of the whole of a motor control device related to one embodiment.

FIG. 2 is a diagram enlarging and showing a connection configuration of one set of an upper arm switching element and a lower arm switching element in a bridge circuit.

FIG. 3 a diagram showing a circuit configuration of a gate driving circuit with a mirror clamp circuit part disposed.

FIG. 4 is a time chart of switching states and gate-to-source voltages of one set of the arm switching elements in the bridge circuit to which the gate driving circuit is coupled.

### DESCRIPTION OF THE EMBODIMENTS

Hereinafter, one embodiment will be described with reference to the drawings.

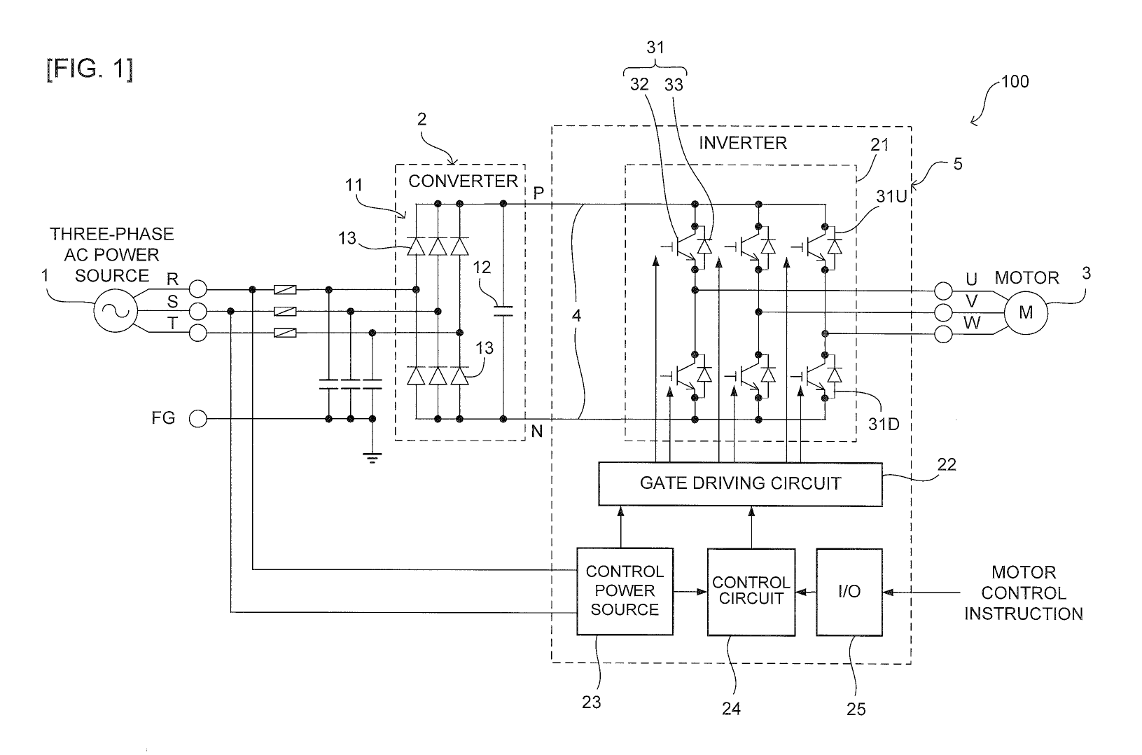

First, a circuit configuration of the whole of a motor control device related to the present embodiment will be described by using FIG. 1. As shown in FIG. 1, a motor control device 100 includes a converter 2 coupled to a three-phase AC power source 1 and an inverter 5 coupled to a motor 3 and coupled also to the converter 2 via DC buses 4.

The converter 2 includes a rectification part 11 and a smoothing capacitor 12. The rectification part 11 is a diode bridge configured by six diodes 13, and full-wave rectifies AC power from the three-phase AC power source 1 and outputs it to the DC buses 4. The smoothing capacitor 12 is coupled so as to bridge the DC buses 4 and smooths DC power obtained by the full-wave rectification of the rectification part 11. With the above configuration, the converter 2 rectifies and smooths the AC power supplied from the three-phase AC power source 1, converts it to the DC power, and outputs the DC power to the DC bus 4 which is configured by one set of two lines of a positive electrode side P line and a negative electrode side N line.

The inverter 5 includes a bridge circuit 21, a gate driving circuit 22, a control power source 23, a control circuit 24, and an I/O 25. Note that the inverter 5 corresponds to an example of an inverter circuit described in each claim.

The bridge circuit 21 is a device in which six arm switching elements 31 configured by semiconductors such as, for example, IGBT, MOSFET are bridge-connected. In detail, the two arm switching elements 31 each configured by connecting in parallel a semiconductor switching element 32 and a diode 33 which is a flywheel diode (FWD) are coupled in series into one set and three sets are coupled to the DC bus 4 in parallel. In them, hereinafter, the arm switching element 31 coupled to the positive electrode side (the P line side) of the DC bus 4 will be referred to as an upper arm switching element 31U and the arm switching element 31 coupled to the negative electrode side (the N line side) thereof will be referred to as a lower arm switching element 31D. An intermediate point between the upper arm switching element 31U and the lower arm switching element 31D of each of the three sets is coupled to the motor 3 corresponding to each phase. Each arm switching element 31 switches between a conductive state (an ON state) and a shutdown state (an OFF state) thereof with respective gate-to-source voltages Vgs1 being controlled by the gate driving circuit 22.

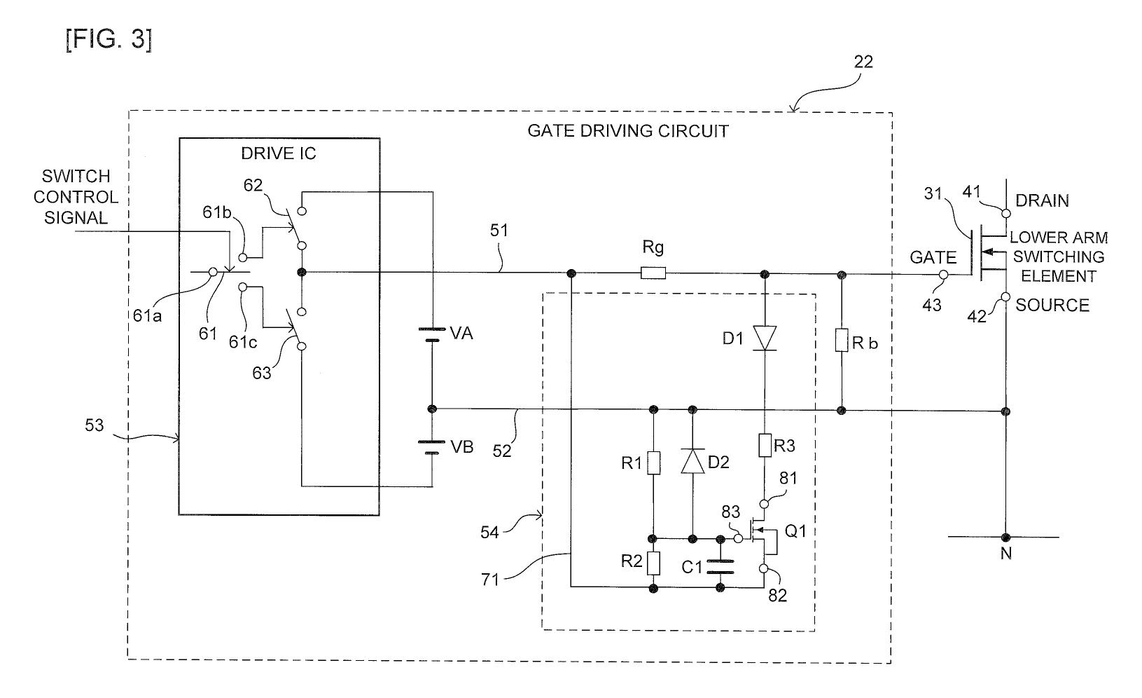

The gate driving circuit 22 switches between the ON state and the OFF state of each of the arm switching elements 31 of the bridge circuit 21 by controlling the gate-to-source voltage Vgs1 thereof on the basis of a switch control signal input from the later described control circuit 24. Note that a specific circuit configuration for controlling the gate-to-source voltage Vgs1 will be described in detail later with reference to FIG. 3.

The control circuit 24 is configured by a CPU and so forth which execute software for power control, and outputs the switch control signal to the gate driving circuit 22 so as to supply desired electric power to the motor 3 on the basis of a motor control instruction which is input from a not shown host controller via the I/O 25, a not shown signal input circuit and so forth. The switch control signal is output by PWM control corresponding to the motor control instruction, and controls the gate driving circuit 22 so as to output the DC power between the DC buses 4 from an intermediate connection position of each set to each of the arm switching elements 31 of the bridge circuit 21 corresponding to each phase of the three-phase AC motor 3. In each set in the bridge circuit 21, when the upper arm switching element 31U and the lower arm switching element 31D in the same set are electrically conducted simultaneously, large current flows into the upper arm switching element 31U and the lower arm switching element 31D and damages both of the arm switching elements 31. In order to prevent such a short-circuit between the DC buses 4, in the PWM control, the switch control signal is output so as not to conduct the upper arm switching element 31U and the lower arm switching element 31D in the same set simultaneously.

The control power source 23 is connected to, for example, two phases of the three-phase AC power source 1 to supply the electric power to each part in the inverter 5.

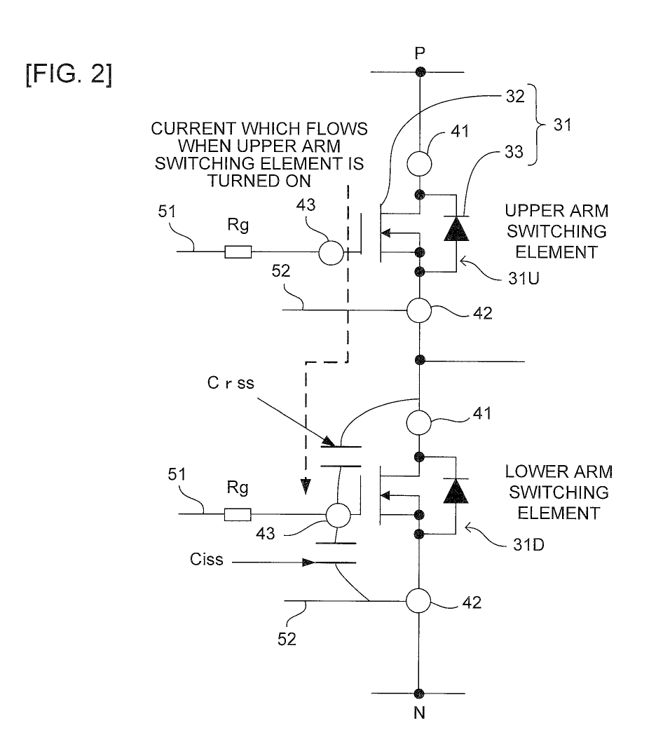

FIG. 2 enlarges and shows a connection configuration of one set of the upper arm switching element 31U and the lower arm switching element 31D in the bridge circuit 21. In the example shown in FIG. 2, each arm switching element 31 is configured by the semiconductor switching element 32 having three electrodes of a drain electrode 41, a source electrode 42, and a gate electrode 43, and the flywheel diode 33 which is connected in parallel with the semiconductor switching element 32 in a direction in which a direction going from the source electrode 42 side to the drain electrode 41 side is set as a forward direction. The source electrode 42 of the upper arm switching element 31U is connected with the drain electrode 41 of the lower arm switching element 31D and thereby the upper and lower two arm switching elements 31U, 31D are connected in series.

Each arm switching element 31 switches conduction or shutdown (ON or OFF) between the drain electrode 41 and the source electrode 42 depending on a high/low relation of potentials between the gate electrode 43 and the source electrode 42, that is, the gate-to-source voltage Vgs1. For example, in a case where an N channel type semiconductor switching element is used as shown in the drawing, it enters the conductive state (the ON state) when the potential of the gate electrode 43 is higher than the potential of the source electrode 42 by a predetermined value (a so-called gate threshold voltage) or more and enters the shutdown state (the OFF state) when it is lower (or equal). In the gate driving circuit 22 which performs such switching control of the arm switching elements 31, switching between the ON state and the OFF state is controlled by switching the high/low relation of potentials between a control line 51 coupled to the gate electrode 43 and an electrode line 52 coupled to the source electrode 42. At this time, it is necessary to dispose a gate resistor Rg on the control line 51 in order to adjust the potential of the gate electrode 43 so as to prevent generation of a surge voltage and to stabilize the operation of the arm switching element 31 concerned.

In the semiconductor switching element 32, however, parasitic capacitances are latently present respectively between the drain electrode 41 and the gate electrode 43 and between the source electrode 42 and the gate electrode 43. Accordingly, for example, as shown in the drawing, in a case where the potential of the drain electrode 41 of the lower arm switching element 31D is suddenly raised (large in dv/dt) due to ON switching (turn-on) of the upper arm switching element 31U, the current flows into a parasitic capacitance (Crss in the drawing) between the drain electrode 41 and the gate electrode 43 thereof and charges it, and further the current flows also into a parasitic capacitance (Ciss in the drawing) between the source electrode 42 and the gate electrode 43 under the influence thereof and charges it. Due to charging of the parasitic capacitances on the both sides in this way, a mirror effect that the potential of the gate electrode 43 is raised occurs and as a result the potential of the gate electrode 43 exceeds an operation threshold (a gate threshold voltage) and thereby there occurs a self-turn-on phenomenon that the lower arm switching element 31D concerned which has been held in the OFF state so far is forcibly brought into the ON state (longitudinally short-circuited). In particular, as dv/dt to be applied to either of the source electrode 42 and the drain electrode 41 becomes larger, a large transient current (dI/dt) flows into the parasitic capacitance and self-turn-on is more likely to occur.

In the configuration of connecting the two arm switching elements 31U, 31D in series between the DC buses 4 in this way as in the bridge circuit 21 of the inverter 5, in a case where the not intended longitudinal short-circuit is caused by self-turn-on, the large current flows between the DC buses 4 and damages the respective arm switching elements 31U, 31D. In particular, in a case where the semiconductor switching element 32 which is fast in switching speed such as SiC, GaN is used in the arm switching element 31, dv/dt to be applied to the other arm switching element 31 which is coupled in series with it becomes large and the self-turn-on is more likely to occur accordingly.

As a countermeasure for preventing such self-turn-on, a configuration in which a resistance value of the gate resistor Rg disposed on the control line 51 is set large so as to delay potential rise of the gate electrode 43 and to slow a connection speed between the drain electrode 41 and the source electrode 42 of the arm switching element 31 concerned (to slow a switching speed) is conceivable. As a result, in the bridge circuit 21, the self-turn-on caused by the mirror effect can be suppressed by slowing a rising speed of the potential to be applied (making dv/dt small) to the electrode of the other arm switching element 31 coupled in series with one arm switching element 31. However, it is not favorable because in this case the switching speed of one arm switching element 31 concerned is slowed and sacrificed. In addition, on the other hand, it is necessary to dispose the gate resistor Rg having a certain resistance value on the control line 51 in order to stabilize the operation also in any of the arm switching elements 31 as described above.

Thus, in the present embodiment, the self-turn-on caused by the mirror effect is suppressed by disposing, in the gate driving circuit 22, a mirror clamp circuit part configured to allow a short-circuit between the both terminals of the gate resistor Rg in the direction going from the gate electrode 43 side terminal to the opposite side terminal only while the arm switching element 31 is in the OFF state.

A circuit configuration diagram of the gate driving circuit 22 of the present embodiment in which the mirror clamp circuit part is disposed is shown in FIG. 3. In FIG. 3, only a part of the gate driving circuit 22 coupled to one lower arm switching element 31D is shown.

The gate driving circuit 22 has the control line 51 coupled to the gate electrode 43 of the arm switching element 31, the electrode line 52 coupled to the source electrode 42, the gate resistor Rg (the gate resistor) disposed on the control line 51, a bias resistor Rb disposed so as to be coupled between the control line 51 and the electrode line 52, a drive IC 53, an upper potential power source VA, a lower potential power source VB, and a mirror clamp circuit part 54 coupled to both of the control line 51 and the electrode line 52.

The drive IC 53 has therein one change-over switch 61 and two connection switches 62, 63. The change-over switch 61 switches as to which one of two other terminals 61b, 61c, a terminal 61a to which the electric power is always supplied (illustration is omitted) is coupled to on the basis of a switch control signal from the control circuit 24. The two connection switches 62, 63 are coupled in series and switch between the conductive state and the shutdown state respectively on the basis of signals which are input from the two terminals 61b, 61c of the change-over switch 61. As a result, switching can be performed such that only one of the two connection switches 62, 63 enters the conductive state and the other enters the shutdown state.

A negative electrode of the upper potential power source VA and a positive electrode of the lower potential power source VB are coupled together. The two serially coupled power sources VA, VB and the two connection switches 62, 63 in the drive IC 53 are coupled in parallel with one another to form a loop circuit. An input side (that is, the opposite side of the gate electrode 43: the left side in the drawing) of the control line 51 is coupled between the two connection switches 62, 63 in the drive IC 53 and an input side (that is, the opposite side of the source electrode 42: the left side in the drawing) of the electrode line 52 is coupled between the negative electrode of the upper potential power source VA and the positive electrode of the lower potential power source VB.

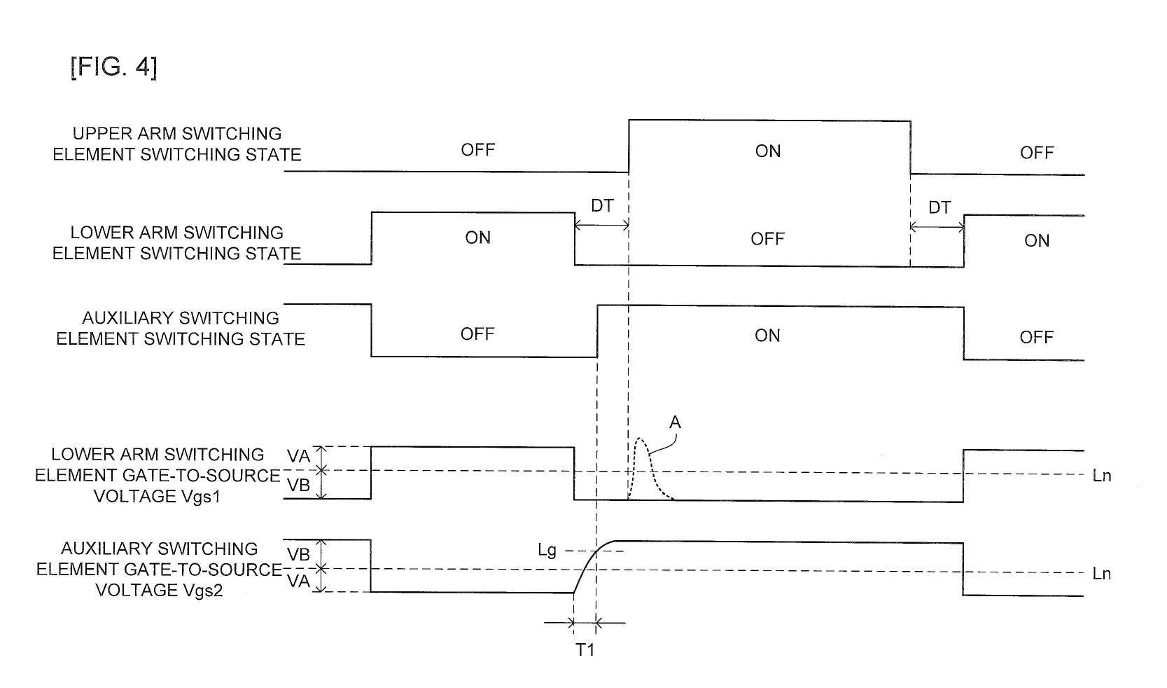

As a result, when only one connection switch 62 is brought into the conductive state and the other connection switch 63 is brought into the shutdown state on the basis of the switch control signal, the potential of the control line 51 can be set higher than the potential of the electrode line 52 (the potential of the negative electrode side N line of the DC bus 4) by the voltage of the upper potential power source VA. In addition, when one connection switch 62 is brought into the shutdown state and only the other connection switch 63 is brought into the conductive state on the basis of the switch control signal, the potential of the control line 51 can be set lower than the potential of the electrode line 52 (the potential of the negative electrode side N line of the DC bus 4) by the voltage of the lower potential power source VB. The high/low relation of the potentials on the respective input sides of the control line 51 and the electrode line 52 is switched with a potential difference of |VA+VB| on the basis of the switch control signal in this way. That is, ON/OFF switching control of the arm switching element 31 concerned is performed by switching the level of the gate-to-source voltage Vgs1 of the arm switching element 31 (see later described FIG. 4). Note that the upper potential power source VA, the lower potential power source VB, and the drive IC 53 correspond to an example of the gate control part described in each claim. In addition, a state where the potential of the control line 51 is set higher than the potential of the electrode line 52 by the voltage of the upper potential power source VA corresponds to a state where the gate control part has output the gate control signal in the description of each claim.

The gate resistor Rg is a resistor which is arranged between the drive IC 53 and the gate electrode 43 of the arm switching element 31 on the control line 51 and is disposed in order to stabilize the operation of the arm switching element 31 concerned as described above, and has a resistance value of such an extent of adjusting the potential of the gate electrode 43. Note that here “arrange” is not physical arrangement among element components on an actual substrate and means arrangement thereof as a connection relation on a circuit (the same shall apply hereinafter).

The bias resistor Rb is a resistor to be disposed in order to appropriately adjust the gate-to-source voltage Vgs1.

The mirror clamp circuit part 54 has a connection line 71 which connects between the both terminals of the gate resistor Rg, and a first diode D1 and an auxiliary switching element Q1 which are respectively disposed on the connection line 71. The first diode D1 is disposed on the connection line 71 in a direction in which the direction going from the gate electrode 43 side terminal of the gate resistor Rg to the opposite side terminal is set as the forward direction. The auxiliary switching element Q1 is a switching element having an auxiliary drain electrode 81, an auxiliary source electrode 82, and an auxiliary gate electrode 83 and is disposed so as to connect the auxiliary drain electrode 81 to the gate electrode 43 side on the connection line 71, to connect the auxiliary source electrode 82 to the side opposite to the gate electrode 43 side on the connection line 71 and to connect the auxiliary gate electrode 83 to the electrode line 52 (the source electrode 42). The auxiliary switching element Q1 controls ON and OFF switching between the auxiliary drain electrode 81 and the auxiliary source electrode 82 depending on the high/low relation of the potentials between the auxiliary gate electrode 83 and the auxiliary source electrode 82, that is, is configured equally (the same N-channel type in the shown example) to the arm switching element 31. Note that the mirror clamp circuit part 54 corresponds to an example of a short circuit part and means for suppressing a self-turn-on phenomenon of the semiconductor switching element caused by a mirror effect described in each claim. In addition, the auxiliary switching element Q1 corresponds to an example of an auxiliary element described in each claim.

In a connection configuration in the mirror clamp circuit part 54, while in the arm switching element 31, the gate electrode 43 is coupled to the control line 51 and the source electrode 42 is coupled to the electrode line 52, in the auxiliary switching element Q1, the auxiliary source electrode 82 is coupled to the control line 51 and the auxiliary gate electrode 83 is coupled to the electrode line 52. That is, the auxiliary gate electrode 83 of the auxiliary switching element Q1 is coupled to the source electrode 42 of the arm switching element 31 and the auxiliary source electrode 82 of the auxiliary switching element Q1 is coupled to the gate electrode 43 of the arm switching element 31. As a result, the arm switching element 31 and the auxiliary switching element Q1 operate such that the ON states and the OFF states thereof become mutually reversed. That is, the auxiliary switching element Q1 conducts the connection line 71 only while the arm switching element 31 is being shut down. In addition, since the first diode D1 is disposed, only a flow of the current going from the gate electrode 43 side terminal of the gate resistor Rg to the reverse side terminal is allowed for the connection line 71. That is, while the arm switching element 31 is being held in the ON state by switching the high/low relation of the potentials between the control line 51 and the electrode line 52, the connection line 71 is shut down and the current flows only into the gate resistor Rg. On the other hand, while the arm switching element 31 is being held in the OFF state, a short circuit is established between the both terminals of the gate resistor Rg only in a direction of the current from the gate electrode 43 side toward the reverse side.

Further, the mirror clamp circuit part 54 further has a capacitor C1 coupled between the auxiliary gate electrode 83 and the auxiliary source electrode 82, a second diode D2 coupled between the auxiliary gate electrode 83 and the electrode line 52 in a direction in which a direction going from the auxiliary gate electrode 83 to the electrode line 52 is set as the forward direction, a first resistor R1 disposed on a line via which the auxiliary gate electrode 83 is coupled to the electrode line 52, a second resistor R2 coupled between the auxiliary gate electrode 83 and the auxiliary source electrode 82, and a third resistor R3 disposed on the auxiliary drain electrode 81 side (the gate electrode 43 side of the arm switching element 31) of the auxiliary switching element Q1 on the connection line 71.

The capacitor C1 has a function of delaying rising of the potential of the auxiliary gate electrode 83, that is, rising of an auxiliary-gate-to-auxiliary-source voltage Vgs2 when the potential of the electrode line 52 is switched higher than the potential of the control line 51 and thereby delaying turn-on (switching from the OFF state to the ON state) of the auxiliary switching element Q1.

The second diode D2 has a function of accelerating discharging of the capacitor C1 when the potential of the control line 51 is switched higher than the potential of the electrode line 52, quickening falling of the auxiliary-gate-to-auxiliary-source voltage Vgs2 and thereby quickening turn-off (switching from the ON state to the OFF state) of the auxiliary switching element Q1.

The first resistor R1 and the second resistor R2 are in a relation of being coupled in series between the control line 51 and the electrode line 52 and have a function of applying an intermediate potential between them to the auxiliary gate electrode 83 as a bias potential by appropriately adjusting respective resistance values. However, in terms of an actual circuit, even when the resistance value of the first resistor R1 is brought into an almost nil state (R1≈0) and the resistance value of the second resistor R2 is brought into an almost insulated state (R2≈∞), the minor clamp circuit part 54 is operable.

The third resistor R3 has a function of applying a load to the connection line 71. However, it is necessary to set the resistance value of the third resistor R3 lower than the resistance value of the gate resistor Rg, and in terms of the actual circuit, even when the resistance value of the third resistor R3 is brought into the almost nil state (R3≈0), the mirror clamp circuit part 54 is operable.

A time chart of switching states and the gate-to-source voltages Vgs1, Vgs2 of one set of the arm switching elements 31 in the bridge circuit 21 to which the gate driving circuit 22 configured as above is coupled is shown in FIG. 4. In FIG. 4, one example of time series variations of the switching state of the upper arm switching element 31U, the switching state of the lower arm switching element 31D, the switching state of the auxiliary switching element Q1 corresponding to the lower arm switching element 31D, the gate-to-source voltage Vgs1 of the lower arm switching element 31D and the auxiliary-gate-to-auxiliary-source voltage Vgs2 of the corresponding auxiliary switching element Q1 is shown.

First, the upper arm switching element 31U and the lower arm switching element 31D in the same set are switch-controlled so as to alternately enter the ON state by PWM control by the control circuit 24. At this time, in order to reliably prevent the upper arm switching element 31U and the lower arm switching element 31D from simultaneously entering into the ON states to short-circuit the DC buses 4, a dead time DT during which both are brought into the OFF states is set between (from the turn-off of one of them to the turn-on of the other) each ON time and each OFF time of each of them uniformly for the same time.

The gate-to-source voltage Vgs1 to be applied to the lower arm switching element 31D so as to make it operate in this way is controlled to be set to a high level (the level which is higher than a potential Ln of the negative electrode side N line of the DC bus 4 by that of the upper potential power source VA: corresponding to an output state of the gate control signal in the description of each claim) only for a period during which the upper arm switching element 31U is in the OFF state and further the lower arm switching element 31D concerned is to be brought into the ON state. In addition, while the upper arm switching element 31U is in the ON state including the dead time DT, the gate-to-source voltage Vgs1 applied to the lower arm switching element 31D is controlled to be set to a low level (the level which is lower than the potential Ln of the negative electrode side N line of the DC bus 4 by that of the lower potential power source VB).

Here, in a case where the mirror clamp circuit part 54 is not coupled to the lower arm switching element 31D, when the lower arm switching element 31D is in the OFF state and the upper arm switching element 31U is turned on, excessive dv/dt is applied to the drain electrode 41 of the lower arm switching element 31D. On this occasion, the potential of the gate electrode 43 is raised higher than the gate threshold voltage due to the above-described mirror effect (see a dotted-line part A in the drawing). Therefore, although the gate-to-source voltage Vgs1 input from the gate driving circuit 22 is still at the low level, the lower arm switching element 31D enters the ON state unintentionally by the self-turn-on effect (not shown in particular). On this occasion, since the upper arm switching element 31U and the lower arm switching element 31D in the same set simultaneously enter the ON states, the DC buses 4 are short-circuited and the large current flows into the both arm switching elements 31 and damages them.

However, in a case where the mirror clamp circuit part 54 is coupled to the lower arm switching element 31D as in the present embodiment, the gate-to-source voltage Vgs1 of the lower arm switching element 31D and the auxiliary-gate-to-auxiliary-source voltage Vgs2 of the auxiliary switching element Q1 are input in opposite phases basically. That is, the lower arm switching element 31D and the auxiliary switching element Q1 operate such that the ON/OFF states thereof are basically reversed. As a result, while the lower arm switching element 31D is in the OFF state and the auxiliary switching element Q1 is in the ON state, the both terminals of the gate resistor Rg are short-circuited via the connection line 71 basically. Accordingly, even when the potential between the gate electrode 43 and the gate resistor Rg tries to rise by the mirror effect, a raised potential thereof is discharged to the control line 51 on the lower potential side (that is, the side reverse to the gate electrode 43 side) of the gate resistor Rg via the connection line 71. The mirror clamp circuit part 54 can prevent the self-turn-on phenomenon of the lower arm switching element 31D in this way.

Note that, in a case where the lower arm switching element 31D and the auxiliary switching element Q1 have simultaneously entered the ON states, the gate resistor Rg ceases to function and the operation of the lower arm switching element 31D becomes unstable. When turn-off of the lower arm switching element 31D and turn-on of the auxiliary switching element Q1 have been simultaneously performed, there is a possibility that they may simultaneously enter the ON states though it is only a short time even in a case where a switching speed of the turn-off of the lower arm switching element 31D is sufficiently fast. In the present embodiment, the potential rising speed of the auxiliary gate electrode 83 can be slowed by connecting the capacitor C1 between the auxiliary gate electrode 83 and the auxiliary source electrode 82, that is, the turn-on of the auxiliary switching element Q1 can be delayed relative to the turn-off of the lower arm switching element 31D. In addition, even the parasitic capacitance of Q1 can be substituted for that of the capacitor C1 in accordance with the capacitance thereof. As a result, the stable operation of the low arm switching element 31D can be maintained. Note that it is necessary to adjust such that the turn-on of the auxiliary switching element Q1 can be completed until a timing when the mirror effect occurs. Specifically, a term T1 taken until the auxiliary-gate-to-auxiliary-source voltage Vgs2 reaches an auxiliary gate threshold voltage Lg after it has begun to rise is adjusted with the time constant of the first resistor R1 and the capacitor C1.

In addition, conversely, in a case where the capacitor C1 is coupled (with the first resistor R1), it is necessary to quickly perform discharging of the capacitor C1 so that the auxiliary switching element Q1 can be swiftly turned off. The capacitor C1 can be quickly discharged and the auxiliary switching element Q1 can be swiftly turned off because the second diode D2 is coupled in a direction in which the direction going from the auxiliary gate electrode 83 to the electrode line 52 is set as the forward direction. As a result, the stable operation of the lower arm switching element 31D can be maintained.

As described above, according to the gate driving circuit 22, the inverter 5, and the motor control device 100 of the present embodiment, the gate driving circuit 22 has the mirror clamp circuit part 54 arranged in parallel with the gate resistor Rg and configured so as to short-circuit the gate resistor Rg. While the mirror clamp circuit part 54 can stabilize the operation of the arm switching element 31 by retaining the function of the gate resistor Rg at the appropriate timing, it can suppress potential rising of the gate electrode 43 and prevent self-turn-on of the arm switching element 31 by short-circuiting the gate resistor Rg at the appropriate timing. As a result, the self-turn-on of the arm switching element 31 caused by the mirror effect can be prevented without lowering the switching speed.

In addition, according to the present embodiment, the mirror clamp circuit part 54 has the connection line 71 connecting between the both terminals of the gate resistor Rg, the first diode D1 arranged on the connection line 71 in a direction in which the direction going from the gate electrode 43 side terminal of the gate resistor Rg to the opposite side terminal is set as the forward direction, and the auxiliary switching element Q1 configured so as to control conduction or shutdown of the connection line 71. As a result, against potential rising of the gate electrode 43 caused by the mirror effect, the auxiliary switching element Q1 conducts the connection line 71 to discharge from the gate resistor Rg toward a low potential side (the side reverse to the gate electrode 43 side) and thereby can suppress potential rising of the gate electrode 43. In this case, the gate resistor Rg may simply have a resistance value of such an extent which is necessary for stabilization. As a result, the self-turn-on of the arm switching element 31 caused by the mirror effect can be prevented without lowering the switching speed by setting the resistance value of the gate resistor Rg large. Note that the mirror clamp circuit part 54 may allow the short-circuit between the both terminals of the gate resistor Rg in the direction going from the gate electrode 43 side terminal to the opposite side terminal and it may be implemented by another circuit configuration.

In addition, according to the present embodiment, the auxiliary switching element Q1 is configured to conduct the connection line 71 only while the arm switching element 31 is held in the OFF state. As a result, the operation can be stabilized via the gate resistor Rg while the high/low relation of the potentials between the control line 51 and the electrode line 52 is switched (that is, the gate control signal is output) to hold the arm switching element 31 in the ON state. In addition, while the arm switching element 31 is held in the OFF state, even when the potential of the gate electrode 43 is raised by the mirror effect, potential rising of the gate electrode 43 can be suppressed and the self-turn-on can be prevented by discharging from the gate resistor Rg toward the low potential side (the side reverse to the gate electrode 43 side) via the connection line 71.

In addition, according to the present embodiment, the auxiliary gate electrode 83 of the auxiliary switching element Q1 is coupled to the source electrode 42 of the arm switching element 31 and the auxiliary source electrode 82 of the auxiliary switching element Q1 is coupled to the gate electrode 43 of the arm switching element 31. As a result, it is possible to make the auxiliary switching element Q1 and the arm switching element 31 perform the operations of switching between the ON state and the OFF state reversely, that is, it is possible to make the auxiliary switching element Q1 conduct the connection line 71 only while the arm switching element 31 is held in the OFF state.

In addition, according to the present embodiment, since the capacitor C1 is arranged between the auxiliary gate electrode 83 and the auxiliary source electrode 82, the potential rising speed (a boosting speed of the auxiliary-gate-to-auxiliary-source voltage Vgs2) of the auxiliary gate electrode 83 can be slowed. That is, the turn-on of the auxiliary switching element Q1 can be delayed relative to the turn-off of the arm switching element 31. As a result, the stable operation of the arm switching element 31 can be maintained.

In addition, according to the present embodiment, since the second diode D2 is arranged between the auxiliary gate electrode 83 and the source electrode 42 in a direction in which the direction going from the auxiliary gate electrode 83 to the source electrode 42 is set as the forward direction, the capacitor C1 can be quickly discharged and the auxiliary switching element Q1 can be swiftly turned off. As a result, the stable operation of the arm switching element 31 can be maintained.

In addition, in particular, in the bridge circuit 21 in which the two arm switching elements 31 are coupled in series, in a case where the switching speed of each arm switching element 31 is fast, the self-turn-on caused by the mirror effect is likely to occur in the aim switching element 31 in the same set. Therefore, application of the gate driving circuit 22 of the present embodiment which can prevent the self-turn-on without lowering the switching speed by setting the resistance value of the gate resistor Rg large is particularly useful.

In addition, other than the already described ones, techniques according to the embodiment and respective variations may be utilized by appropriately combining them together.

In addition, though not illustrated one by one, the embodiment and the respective variations are carried out by being modified in a variety of ways within a range not deviating from the gist thereof.

What is claimed is:

1. A gate driving circuit configured to control conduction or shutdown of a semiconductor switching element, comprising:
a gate control part configured to output a gate control signal for controlling the conduction or the shutdown of the semiconductor switching element;
a gate resistor coupled between the gate control part and a gate electrode of the semiconductor switching element; and
a short circuit part coupled in parallel with the gate resistor and configured to shirt-circuit the gate resistor.

2. The gate driving circuit according to claim 1,
wherein the short circuit part comprises
a connection line coupling between both terminals of the gate resistor,
a first diode coupled to the connection line so that a direction going from a gate electrode side terminal to an opposite side terminal of the gate resistor is set as a forward direction, and
an auxiliary element configured to control conduction or shutdown of the connection line.

3. The gate driving circuit according to claim 2,
wherein the auxiliary element is configured to conduct the connection line while the semiconductor switching element is shut down.

4. The gate driving circuit according to claim 3,
wherein the auxiliary element comprises
an auxiliary gate electrode coupled to a source electrode of the semiconductor switching element, and
an auxiliary source electrode coupled to the gate electrode of the semiconductor switching element.

5. The gate driving circuit according to claim 4,
wherein the short circuit part comprises
a capacitor coupled between the auxiliary gate electrode and the auxiliary source electrode.

6. The gate driving circuit according to claim 5,
wherein the short circuit part comprises
a second diode coupled between the auxiliary gate electrode and the source electrode so that a direction going from the auxiliary gate electrode to the source electrode is set as a forward direction.

7. A gate driving circuit configured to control conduction or shutdown of a semiconductor switching element, comprising:
means for suppressing a self-turn-on phenomenon of the semiconductor switching element caused by a mirror effect.

8. An inverter circuit configured to supply electric power to a motor, comprising:
a bridge circuit in which a plurality of sets each including two semiconductor switching elements coupled in series are coupled in parallel with one another between DC buses; and
a gate driving circuit configured to respectively control conduction or shutdown of the plurality of semiconductor switching elements in the bridge circuit,
the gate driving circuit comprising:
a gate control part configured to output a gate control signal for controlling the conduction or the shutdown of the semiconductor switching element;
a gate resistor coupled between the gate control part and a gate electrode of the semiconductor switching element; and
a short circuit part coupled in parallel with the gate resistor and configured to shirt-circuit the gate resistor.

9. A motor control device configured to drive a motor, comprising:
an inverter circuit;
a rectification part configured to rectify an AC voltage from an AC power source to a DC voltage and to supply the DC voltage to DC buses; and
a smoothing capacitor configured to smooth the DC voltage between the DC buses rectified by the rectification part,
the inverter circuit comprising:
a bridge circuit in which a plurality of sets each including two semiconductor switching elements coupled in series are coupled in parallel with one another between the DC buses; and
a gate driving circuit configured to respectively control conduction or shutdown of the plurality of semiconductor switching elements in the bridge circuit,
the gate driving circuit comprising:
a gate control part configured to output a gate control signal for controlling the conduction or the shutdown of the semiconductor switching element;
a gate resistor coupled between the gate control part and a gate electrode of the semiconductor switching element; and
a short circuit part coupled in parallel with the gate resistor and configured to shirt-circuit the gate resistor.
